(19) United States
(12) Patent Application Publication
(10) Pub. No.: US 2024/0188306 A1
(43) Pub. Date: Jun. 6, 2024

(54) RESISTIVE MEMORY DEVICE

(71) Applicant: UNITED MICROELECTRONICS CORP., Hsin-Chu City (TW)

(72) Inventors: Wen-Jen Wang, Tainan City (TW); Yu-Huan Yeh, Hsinchu City (TW); Chuan-Fu Wang, Miaoli County (TW); Hsiang-Hung Peng, Hsinchu County (TW)

(73) Assignee: UNITED MICROELECTRONICS CORP., Hsin-Chu City (TW)

(21) Appl. No.: 18/096,532

(22) Filed: Jan. 12, 2023

(30) Foreign Application Priority Data
Dec. 6, 2022 (TW) 111146778

(51) Int. Cl. H10B 63/00

(52) U.S. Cl. CPC H10B 63/82

(57) ABSTRACT

A resistive memory device includes a dielectric layer, a first via connection structure, a first stacked structure, and a first insulating structure. The first via connection structure is disposed in the dielectric layer. The first stacked structure is disposed on the first via connection structure and the dielectric layer. The first insulating structure penetrates through a portion of the first stacked structure in a vertical direction and divides the first stacked structure into a first cell unit and a second cell unit. The first cell unit and the second cell unit include a first shared bottom electrode, and the first insulating structure is disposed directly on the first shared bottom electrode.

### BACKGROUND OF THE INVENTION

### 1. Field of the Invention

The present invention relates to a resistive memory device, and more particularly, to a resistive memory device including an insulating structure and a shared bottom electrode.

### 2. Description of the Prior Art

Semiconductor memory devices are used in computer and electronics industries as a means for retaining digital information or data. Typically, the semiconductor memory devices are divided into volatile and non-volatile memory devices. The volatile memory device is a computer memory that loses its stored data when power to the operation is interrupted. Comparatively, in the non-volatile memory device, the stored data will not be lost when the power supply is interrupted. The resistive random access memory (RRAM) is a kind of non-volatile memory technology having the characteristics of low operating voltage, low power consumption, and high writing speed and is regarded as a memory structure that can be applied to many electronic devices.

### SUMMARY OF THE INVENTION

A resistive memory device is provided in the present invention. An insulating structure penetrating through a portion of a stacked structure is used to divide the stacked structure into two memory cell units including a shared bottom electrode. The purposes of shrinking the dimension of a single memory cell unit, increasing the density of the memory cell units, and/or improving operation efficiency may be achieved accordingly.

According to an embodiment of the present invention, a resistive memory device is provided. The resistive memory device includes a dielectric layer, a first via connection structure, a first stacked structure, and a first insulating structure. The first via connection structure is disposed in the dielectric layer, and the first stacked structure is disposed on the first via connection structure and the dielectric layer. The first insulating structure penetrates through a portion of the first stacked structure in a vertical direction and divides the first stacked structure into a first memory cell unit and a second memory cell unit. The first memory cell unit and the second memory cell unit include a first shared bottom electrode, and the first insulating structure is disposed directly on the first shared bottom electrode.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a top view schematic drawing illustrating a resistive memory device according to a first embodiment of the present invention.

FIG. 2 is a cross-sectional schematic diagram taken along a line A-A′ in FIG. 1.

FIG. 3 is a cross-sectional schematic diagram taken along a line B-B′ in FIG. 1.

FIGS. 4-7 are schematic drawings illustrating a manufacturing method of the resistive memory device according to an embodiment of the present invention, wherein FIG. 5 is a schematic drawing in a step subsequent to FIG. 4, FIG. 6 is a schematic drawing in a step subsequent to FIG. 5, and FIG. 7 is a schematic drawing in a step subsequent to FIG. 6.

FIGS. 8-10 are schematic drawings illustrating a manufacturing method of the resistive memory device according to another embodiment of the present invention, wherein FIG. 9 is a schematic drawing in a step subsequent to FIG. 8, and FIG. 10 is a schematic drawing in a step subsequent to FIG. 9.

FIG. 11 is a top view schematic drawing illustrating a resistive memory device according to a second embodiment of the present invention.

FIG. 12 is a top view schematic drawing illustrating a resistive memory device according to a third embodiment of the present invention.

FIG. 13 is a schematic drawing illustrating a resistive memory device according to a fourth embodiment of the present invention.

### DETAILED DESCRIPTION

The present invention has been particularly shown and described with respect to certain embodiments and specific features thereof. The embodiments set forth herein below are to be taken as illustrative rather than limiting. It should be readily apparent to those of ordinary skill in the art that various changes and modifications in form and detail may be made without departing from the spirit and scope of the present invention.

Before the further description of the preferred embodiment, the specific terms used throughout the text will be described below.

The terms “on,” “above,” and “over” used herein should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

The ordinal numbers, such as “first”, “second”, etc., used in the description and the claims are used to modify the elements in the claims and do not themselves imply and represent that the claim has any previous ordinal number, do not represent the sequence of some claimed element and another claimed element, and do not represent the sequence of the manufacturing methods, unless an addition description is accompanied. The use of these ordinal numbers is only used to make a claimed element with a certain name clear from another claimed element with the same name.

The term “etch” is used herein to describe the process of patterning a material layer so that at least a portion of the material layer after etching is retained. When “etching” a material layer, at least a portion of the material layer is retained after the end of the treatment. In contrast, when the material layer is “removed”, substantially all the material layer is removed in the process. However, in some embodiments, “removal” is considered to be a broad term and may include etching.

The term “forming” or the term “disposing” are used hereinafter to describe the behavior of applying a layer of material to the substrate. Such terms are intended to describe any possible layer forming techniques including, but not limited to, thermal growth, sputtering, evaporation, chemical vapor deposition, epitaxial growth, electroplating, and the like.

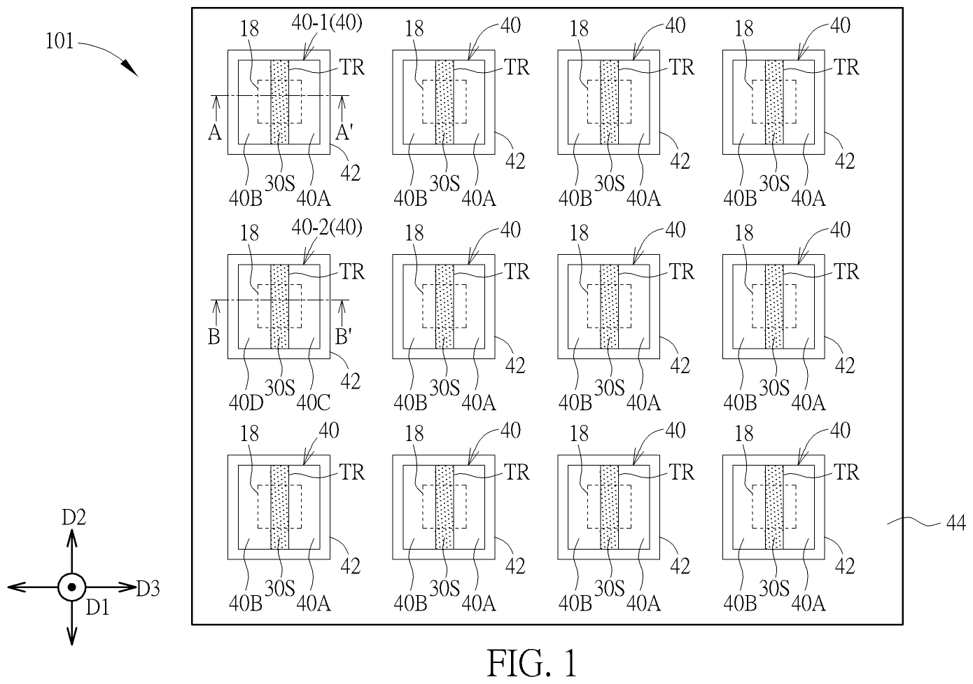

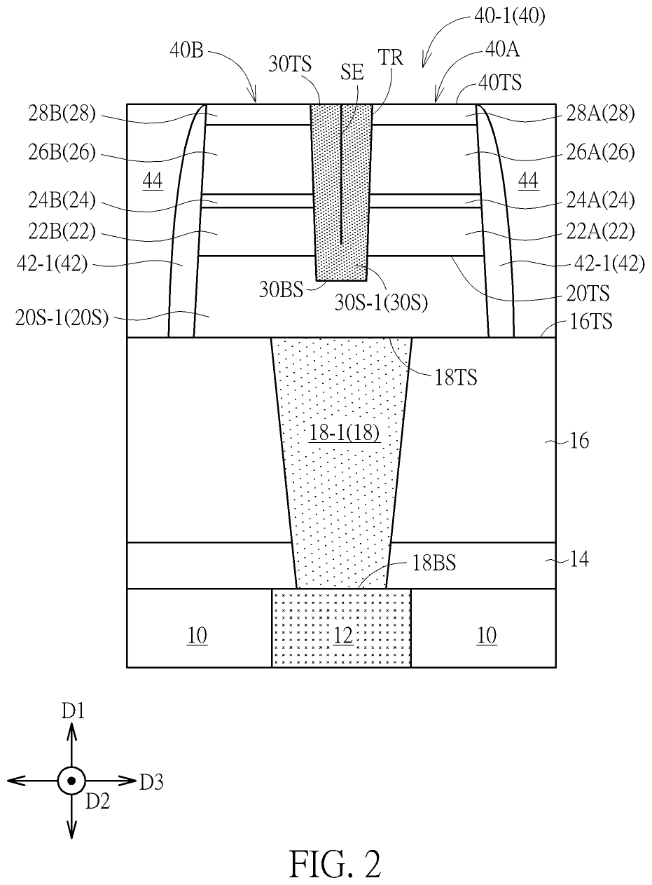

Please refer to FIG. 1. FIG. 2. FIG. 1 is a top view schematic drawing illustrating a resistive memory device 101 according to a first embodiment of the present invention, and FIG. 2 is a cross-sectional schematic diagram taken along a line A-A′ in FIG. 1. As shown in FIG. 1, in some embodiments, the resistive memory device 101 may include a plurality of stacked structures 40 arranged in an array configuration, each of the stacked structures 40 may be disposed on the corresponding via connection structure 18 in a vertical direction (such as a direction D1), and each of the stacked structures 40 may be divided into two memory cell units by the corresponding insulating structure 30S. In some embodiments, two stacked structures 40 disposed adjacent to each other in a direction D2 may be regarded as a first stacked structure 40-1 and a second stacked structure 40-2, but not limited thereto. Additionally, in some embodiments, the resistive memory device may include only one memory cell unit according to some design considerations. As shown in FIG. 1 and FIG. 2, the resistive memory device 101 may include a dielectric layer 16, a via connection structure 18 (such as a first via connection structure 18-1), a stacked structure 40 (such as a first stacked structure 40-1), and an insulating structure 30S (such as a first insulating structure 30S-1). The first via connection structure 18-1 is disposed in the dielectric layer 16, and the first stacked structure 40-1 is disposed on the first via connection structure 18-1 and the dielectric layer 16. The first insulating structure 30S-1 penetrates through a portion of the first stacked structure 40-1 in a vertical direction (such as the direction D1) and divides the first stacked structure 40-1 into a first memory cell unit 40A and a second memory cell unit 40B. The first memory cell unit 40A and the second memory cell unit 40B include a first shared bottom electrode 20S-1, and the first insulating structure 30S-1 is disposed directly on the first shared bottom electrode 20S-1. In other words, the first insulating structure 30S-1 does not penetrate through the first shared bottom electrode 20S-1, and the first shared bottom electrode 20S-1 may be shared by the first memory cell unit 40A and the second memory cell unit 40B. The dimension of a single memory cell unit may be reduced by using the insulating structure 30S dividing the stacked structure 40 into two memory cell units partially separated from each other, and the distribution density of the memory cell units may be increased accordingly.

In some embodiments, the resistive memory device 101 may further include a dielectric layer 10, an electrically conductive line 12, and a dielectric layer 14. The electrically conductive line 12 may be disposed in the dielectric layer 10, the dielectric layer 14 may be disposed between the dielectric layer 16 and the dielectric layer 10, and the via connection structure 18 may penetrate through the dielectric layer 16 and the dielectric layer 14 located on the electrically conductive line 12 in the direction D1. A bottom surface 18BS of the via connection structure 18 may contact and be electrically connected with the electrically conductive line 12, and a top surface 18TS of the via connection structure 18 and a top surface 16TS of the dielectric layer 16 may be substantially coplanar, but not limited thereto. It is worth noting that, in this description, a top surface of a specific component may include the topmost surface of this component in the direction D1, and a bottom surface of a specific component may include the bottommost surface of this component in the direction D1, but not limited thereto. In some embodiments, the dielectric layer 10, the dielectric layer 14, and the dielectric layer 16 may include silicon oxide, silicon nitride, nitrogen doped carbide (NDC), fluorosilicate glass (FSG), or other suitable dielectric materials, and the via connection structure 18 and the electrically conductive line 12 may include a low electrical resistivity material and a barrier layer, but not limited thereto. The low electrical resistivity material described above may include a material with relatively low electrical resistivity, such as copper, aluminum, tungsten, and so forth, and the barrier layer described above may include titanium nitride, tantalum nitride, or other suitable electrically conductive barrier materials, but not limited thereto. In some embodiments, the dielectric layer 10 may be disposed on a substrate (not illustrated), and the substrate may include a semiconductor substrate, such as silicon substrate, silicon germanium substrate, silicon-on-insulator (SOI) substrate, or a substrate made of other suitable materials. In addition, before the step of forming the dielectric layer 10, other units (such as transistors) and/or other circuits (not illustrated) may be formed on the substrate described above, and the electrically conductive line 12 may be electrically connected downwardly with the units and/or the circuits on the substrate, but not limited thereto. In some embodiments, the manufacturing method of the resistive memory device 101 may be integrated with the back end of line (BEOL) process in the semiconductor manufacturing process. The dielectric layer 10, the dielectric layer 14, and the dielectric layer 16 described above may be regarded as interlayer dielectric layers formed in the BEOL process, and the electrically conductive line 12 and the via connection structure 18 described above may be regarded as a portion of an interconnection structure formed in the BEOL process, but not limited thereto.

In some embodiments, the vertical direction described above (such as the direction D1) may be regarded as a thickness direction of the dielectric layer 10 and/or the dielectric layer 16. The dielectric layer 10 may have a top surface and a bottom surface opposite to the top surface in the direction D1, and the dielectric layer 16, the via connection structure 18, the stacked structure 40, and the insulating structure 30S may be disposed at the side of the top surface of the dielectric layer 10. Horizontal directions substantially orthogonal to the direction D1 (such as the direction D2, a direction D3, and other directions orthogonal to the direction D1) may be substantially parallel with the top surface and/or the bottom surface of the dielectric layer 10, but not limited thereto. In this description, a distance between the bottom surface of the dielectric layer 10 and a relatively higher location and/or a relatively higher part in the vertical direction (such as the direction D1) may be greater than a distance between the bottom surface of the dielectric layer 10 and a relatively lower location and/or a relatively lower part in the direction D1. The bottom or a lower portion of each component may be closer to the bottom surface of the dielectric layer 10 in the direction D1 than the top or upper portion of this component. Another component disposed above a specific component may be regarded as being relatively far from the bottom surface of the dielectric layer 10 in the direction D1, and another component disposed under a specific component may be regarded as being relatively close to the bottom surface of the dielectric layer 10 in the direction D1.

In some embodiments, the stacked structure 40 (such as the first stacked structure 40-1) may include a shared bottom electrode 20S (such as the first shared bottom electrode 20S-1), a variable resistance material 22, and an electrically conductive layer 26 disposed stacked in the direction D1. The first shared bottom electrode 20S-1 may be disposed on the dielectric layer 16 and the first via connection structure 18-1, the variable resistance material 22 and the electrically conductive layer 26 may be disposed above the first shared bottom electrode 20S-1 in the direction D1, and the variable resistance material 22 may be disposed between the first shared bottom electrode 20S-1 and the electrically conductive layer 26 in the direction D1. The shared bottom electrode 20S (such as the first shared bottom electrode 20S-1) and the electrically conductive layer 26 may respectively include an electrically conductive material, such as platinum, tungsten, silver, copper, titanium, tantalum, an alloy of the materials described above, electrically conductive nitride of the materials described above, or other suitable electrically conductive materials. The variable resistance material 22 may include metal oxide, such as transition metal oxide, perovskite oxide, or other suitable variable resistance materials. The insulating structure 30S (such as the first insulating structure 30S-1) may penetrate through the electrically conductive layer 26 and the variable resistance material 22 in the direction D1 and divide the electrically conductive layer 26 and the variable resistance material 22 into two portions separated from each other, respectively. The insulating structure 30S may include a single layer or multiple layers of insulating materials, such as a nitride insulating material (silicon nitride, for example) or other suitable insulating materials (such as dielectric materials with low dielectric constant). In some embodiments, there may be a seam SE in the insulating structure 30S, and an air gap may exist within the seam SE, but not limited thereto.

In some embodiments, the first memory cell unit 40A may further include a first top electrode 26A and a first variable resistance layer 22A, and the second memory cell unit 40B may further include a second top electrode 26B and a second variable resistance layer 22B. The first top electrode 26A, the first variable resistance layer 22A, the second top electrode 26B, and the second variable resistance layer 22B may be disposed above the first shared bottom electrode 20S-1 in the direction D1. The first variable resistance layer 22A may be disposed between the first shared bottom electrode 20S-1 and the first top electrode 26A in the direction D1. The second variable resistance layer 22B may be disposed between the first shared bottom electrode 20S-1 and the second top electrode 26B in the direction D1. In some embodiments, the first variable resistance layer 22A may be a first portion of the variable resistance material 22, the second variable resistance layer 22B may be a second portion of the variable resistance material 22, and the first portion of the variable resistance material 22 and the second portion of the variable resistance material 22 may be separated from each other by the first insulating structure 30S-1. Therefore, the material composition of the first variable resistance layer 22A may be identical to that of the second variable resistance layer 22B, and the thickness of the first variable resistance layer 22A may be substantially equal to the thickness of the second variable resistance layer 22B, but not limited thereto. In some embodiments, the first top electrode 26A may be a first portion of the electrically conductive layer 26, the second top electrode 26B may be a second portion of the electrically conductive layer 26, and the first portion of the electrically conductive layer 26 and the second portion of the electrically conductive layer 26 may be separated from each other by the first insulating structure 30S-1. Therefore, the material composition of the first top electrode 26A may be identical to that of the second top electrode 26B, and the thickness of the first top electrode 26A may be substantially equal to the thickness of the second top electrode 26B, but not limited thereto. In each memory cell unit, each variable resistance material layer may be regarded as a switching medium in the resistive memory cell unit. The resistance of the resistive memory cell unit may be changed by applying suitable voltage to the top electrode and the bottom electrode in the stacked structure, and the resistive memory cell unit may switch to high resistance state (HRS) or low resistance state (LRS) for realizing the operation mode of the memory device, such as storing data, reading data, and resetting. Additionally, by using the insulating structure 30S dividing the stacked structure 40 into the first memory cell unit 40A and the second memory cell unit 40B partially separated from each other and including the shared bottom electrode, the dimension of the single memory cell unit may be reduced for increasing the distribution density of the memory cell units. The operation time of the single memory cell unit may be relatively reduced by shrinking the dimension of the memory cell unit. For instance, the forming time required to form conductive path and switch to the low resistance state by applying voltage bias to the memory cell unit may be reduced by shrinking the dimension of the memory cell unit, and the operation efficiency may be enhanced accordingly.

In some embodiments, the stacked structure 40 (such as the first stacked structure 40-1) may further include a barrier layer 24 and a capping layer 28. The barrier layer 24 may be disposed between the variable resistance material 22 and the electrically conductive layer 26 in the direction D1 for blocking the material of the electrically conductive layer 26 or other materials from entering the variable resistance material 22 and influencing the material characteristics of the variable resistance material 22 and/or reducing the amount of the material of the electrically conductive layer 26 or other materials entering the variable resistance material 22 and influencing the material characteristics of the variable resistance material 22. The capping layer 28 may be disposed on the electrically conductive layer 26. The barrier layer 24 may include iridium or other suitable barrier materials, and the capping layer 28 may include an oxide insulation material (such as silicon oxide) or other suitable insulation materials. In some embodiments, the first memory cell unit 40A may further include a first barrier layer 24A and a first capping layer 28A, and the second memory cell unit 40B may further include a second barrier layer 24B and a second capping layer 28B. The first barrier layer 24A may be disposed between the first variable resistance layer 22A and the first top electrode 26A in the direction D1, and the second barrier layer 24B may be disposed between the second variable resistance layer 22B and the second top electrode 26B in the direction D1. The first capping layer 28A may be disposed on the first top electrode 26A, and the second capping layer 28B may be disposed on the second top electrode 26B. In some embodiments, the first barrier layer 24A and the second barrier layer 24B may be two portions of the barrier layer 24 separated from each other by the insulating structure 30S. Therefore, the material composition of the first barrier layer 24A may be identical to that of the second barrier layer 24B, and the thickness of the first barrier layer 24A may be substantially equal to the thickness of the second barrier layer 24B. In some embodiments, the first capping layer 28A and the second capping layer 28B may be two portions of the capping layer 28 separated from each other by the insulating structure 30S. Therefore, the material composition of the first capping layer 28A may be identical to that of the second capping layer 28B, and the thickness of the first capping layer 28A may be substantially equal to the thickness of the second capping layer 28B. It is worth noting that, the stacked structure 40 in the present invention is not limited to the condition described above and other material layers may be disposed in the stacked structure 40 according to some design considerations. Relatively, other material layers may be disposed in each memory cell unit according to some design considerations also. Additionally, the resistive memory device 101 may further include a spacer structure 42 (such as a first spacer structure 42-1) and a dielectric layer 44. The first spacer structure 42-1 may be disposed on a sidewall of the first stacked structure 40-1, and the dielectric layer 44 may be disposed on the dielectric layer 16 and surround the first spacer structure 42-1, the first stacked structure 40-1, and the first insulating structure 30S-1 in the horizontal directions (such as the direction D2 and the direction D3 perpendicular to the direction D1). The spacer structure 42 may include a single layer or multiple layers of dielectric materials, such as silicon nitride, silicon carbonitride, or other suitable dielectric materials, and the dielectric layer 44 may include silicon oxide, silicon nitride, or other suitable dielectric materials.

In some embodiments, the first memory cell unit 40A and the second memory cell unit 40B may be located at two opposite sides of the first insulating structure 30S-1 in a horizontal direction (such as the direction D3), respectively, and the first insulating structure 30S-1 may directly contact the first memory cell unit 40A and the second memory cell unit 40B. In other words, a sidewall of the first insulating structure 30S-1 may be directly connected with the first capping layer 28A, the first top electrode 26A, the first barrier layer 24A, and the first variable resistance layer 22A in the first memory cell unit 40A, and another sidewall of the first insulating structure 30S-1 may be directly connected with the second capping layer 28B, the second top electrode 26B, the second barrier layer 24B, and the second variable resistance layer 22B in the second memory cell unit 40B. In some embodiments, at least a portion of the first insulating structure 30S-1 may be disposed above the first via connection structure 18-1 in the direction D1, and the first insulating structure 30S-1 does not penetrate through the first shared bottom electrode 20S-1. Therefore, a portion of the first shared bottom electrode 20S-1 may be disposed between the first insulating structure 30S-1 and the first via connection structure 18-1 in the direction D1. In some embodiments, a bottom surface 30BS of the first insulating structure 30S-1 may be lower than a top surface 20TS of the first shared bottom electrode 20S-1 and higher than the top surface 18TS of the first via connection structure 18-1 in the direction D1. Therefore, the first insulating structure 30S-1 may extend to be partially located in the first shared bottom electrode 20S-1 without penetrating through the whole first shared bottom electrode 20S-1 for ensuring that the variable resistance material 22 is divided into the first variable resistance layer 22A and the second variable resistance layer 22B separated from each other. In addition, by the design of the shared bottom electrode 20S, the damage generated by the process of forming the insulating structure 30S to the via connection structure 18 may be avoided and/or the contact area between the shared bottom electrode 20S and the via connection structure 18 may be relatively increased, and that is beneficial for the operation performance and/or the manufacturing yield of the resistive memory device.

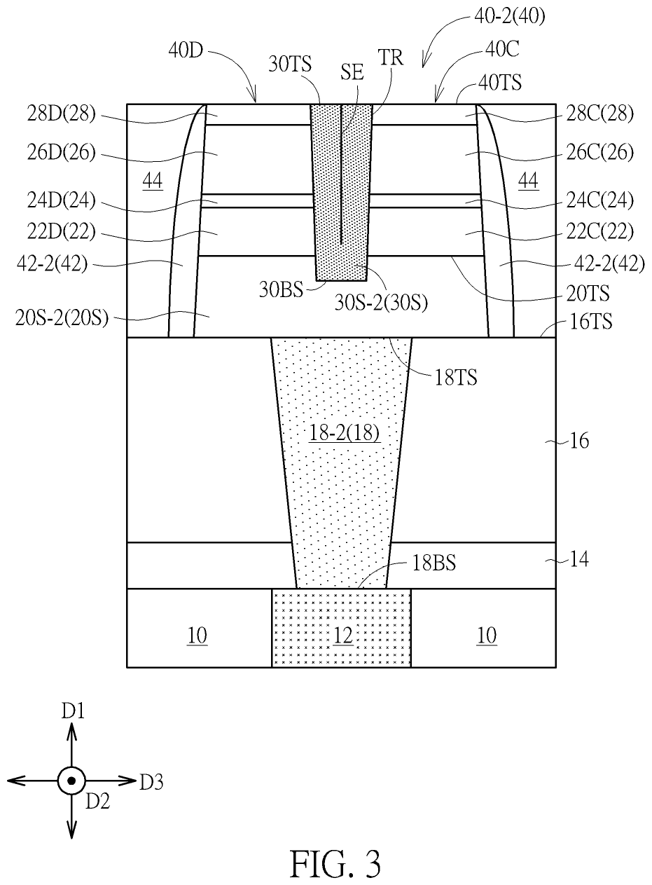

As shown in FIG. 1, in some embodiments, the resistive memory device 101 may include a plurality of stacked structures 40 arranged in an array configuration, and the two stacked structures 40 located adjacent to each other in the direction D2 may be regarded as a first stacked structure 40-1 and a second stacked structure 40-2, respectively. Therefore, as shown in FIG. 1 and FIG. 3, the resistive memory device 101 may include the second stacked structure 40-2, a second via connection structure 18-2, and a second insulating structure 30S-2 located corresponding to the second stacked structure 40-2. The second via connection structure 18-2 may be disposed in the dielectric layer 16 and the dielectric layer 14. The second stacked structure 40-2 may be disposed on the second via connection structure 18-2 and the dielectric layer 16, and the second insulating structure 30S-2 may penetrate through a portion of the second stacked structure 40-2 in the direction D1 and divide the second stacked structure 40-2 into a third memory cell unit 40C and a fourth memory cell unit 40D. The third memory cell unit 40C and the fourth memory cell unit 40D may include a second shared bottom electrode 20S-2, and the second insulating structure 30S-2 may be disposed directly on the second shared bottom electrode 20S-2. In some embodiments, the material compositions and the relative allocations of the second via connection structure 18-2, the second stacked structure 40-2, and the second insulating structure 30S-2 may be identical to those of the first via connection structure 18-1, the first stacked structure 40-1, and the first insulating structure 30S-1 illustrated in FIG. 2 described above, but not limited thereto. For example, the second stacked structure 40-2 may include a shared bottom electrode 20S (such as the second shared bottom electrode 20S-2), a variable resistance material 22, a barrier layer 24, an electrically conductive layer 26, and a capping layer 28 disposed and stacked in the direction D1, but not limited thereto. In some embodiments, the material composition of the second insulating structure 30S-2 and/or the second stacked structure 40-2 may be different from that of the first insulating structure 30S-1 and/or the first stacked structure 40-1 according to some design considerations.

As shown in FIG. 1 and FIG. 3, in some embodiments, the third memory cell unit 40C may include a third variable resistance layer 22C, a third barrier layer 24C, a third top electrode 26C, and a third capping layer 28C disposed and stacked in the direction D1, and the fourth memory cell unit 40D may include a fourth variable resistance layer 22D, a fourth barrier layer 24D, a fourth top electrode 26D, and a fourth capping layer 28D disposed and stacked in the direction D1. The third variable resistance layer 22C may be disposed between the second shared bottom electrode 20S-2 and the third top electrode 26C in the direction D1, the third barrier layer 24C may be disposed between the third variable resistance layer 22C and the third top electrode 26C in the direction D1, and the third capping layer 28C may be disposed on the third top electrode 26C. Comparatively, the fourth variable resistance layer 22D may be disposed between the second shared bottom electrode 20S-2 and the fourth top electrode 26D in the direction D1, the fourth barrier layer 24D may be disposed between the fourth variable resistance layer 22D and the fourth top electrode 26D in the direction D1, and the fourth capping layer 28D may be disposed on the fourth top electrode 26D. The third variable resistance layer 22C and the fourth variable resistance layer 22D may be different portions of the variable resistance material 22 separated from each other by the second insulating structure 30S-2. The third barrier layer 24C and the fourth barrier layer 24D may be different portions of the barrier layer 24 separated from each other by the second insulating structure 30S-2. The third top electrode 26C and the fourth top electrode 26D may be different portions of the electrically conductive layer 26 separated from each other by the second insulating structure 30S-2. The third capping layer 28C and the fourth capping layer 28D may be different portions of the capping layer 28 separated from each other by the second insulating structure 30S-2. A sidewall of the second insulating structure 30S-2 may be directly connected with the third capping layer 28C, the third top electrode 26C, the third barrier layer 24C, and the third variable resistance layer 22C in the third memory cell unit 40C, and another sidewall of the second insulating structure 30S-2 may be directly connected with the fourth capping layer 28D, the fourth top electrode 26D, the fourth barrier layer 24D, and the fourth variable resistance layer 22D in the fourth memory cell unit 40D.

As shown in FIGS. 1-3, the first stacked structure 40-1 and the second stacked structure 40-2 may be separated from each other, and the first shared bottom electrode 20S-1 and the second shared bottom electrode 20S-2 may be separated from each other. The spacer structure 42 disposed on the sidewall of the first stacked structure 40-1 may be the first spacer structure 42-1, and the spacer structure 42 disposed on the sidewall of the second stacked structure 40-2 may be a second spacer structure 42-2. In some embodiments, each of the insulating structures 30S may extend in the direction D2, and each of the spacer structures 42 may surround the corresponding stacked structure 40 in the horizontal directions and be directly connected with the corresponding insulating structure 30S. Therefore, the first insulating structure 30S-1 and the second insulating structure 30S-2 may extend in the direction D2 respectively, and the first insulating structure 30S-1 and the second insulating structure 30S-2 may be disposed adjacent to each other in the direction D2 and disposed separated from each other. The first spacer structure 42-1 may be directly connected with two opposite sidewalls of the first insulating structure 30S-1 in the direction D2, and the second spacer structure 42-2 may be directly connected with two opposite sidewalls of the second insulating structure 30S-2 in the direction D2.

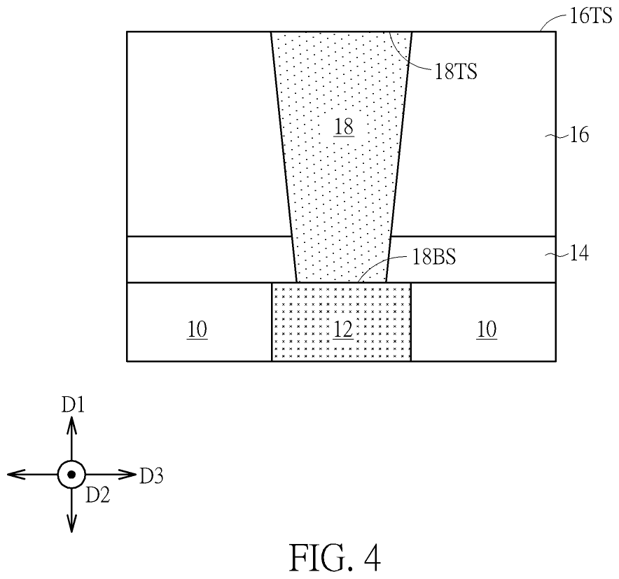

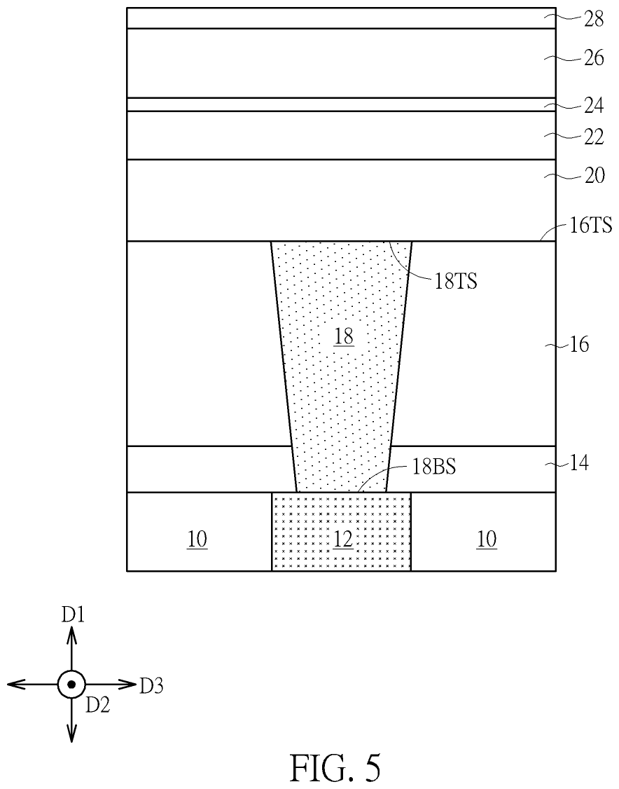

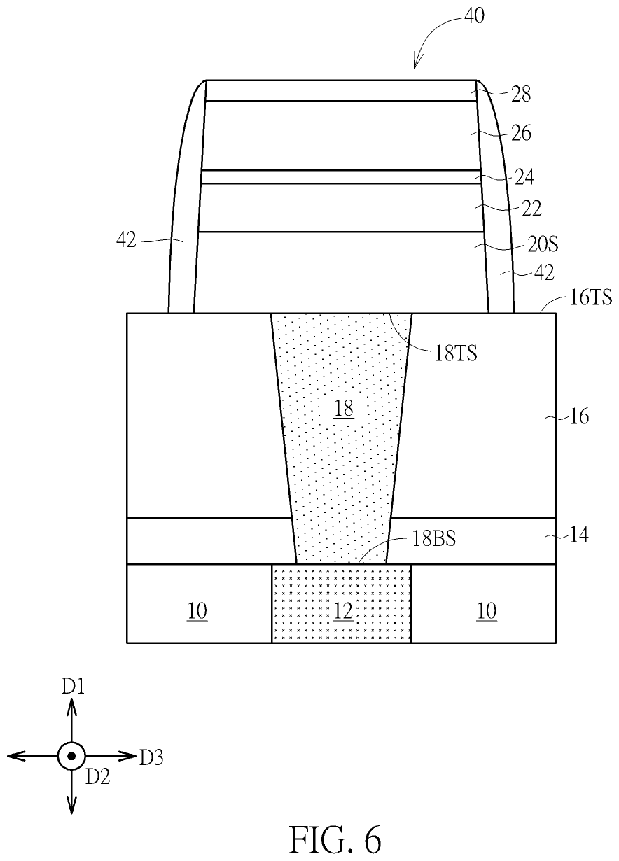

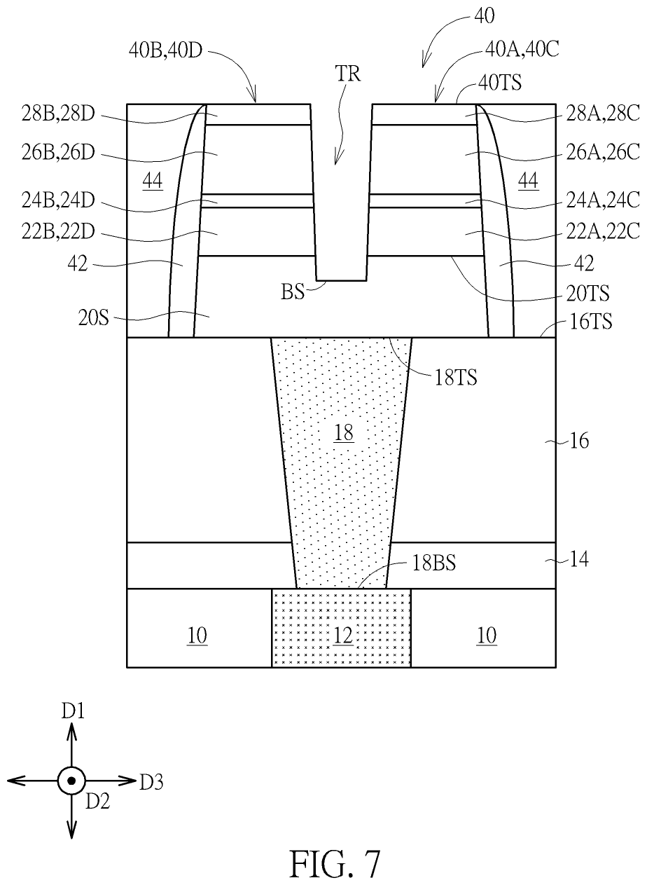

Please refer to FIGS. 1-3 and FIGS. 4-7. FIGS. 4-7 are schematic drawings illustrating a manufacturing method of the resistive memory device according to an embodiment of the present invention, wherein FIG. 5 is a schematic drawing in a step subsequent to FIG. 4, FIG. 6 is a schematic drawing in a step subsequent to FIG. 5, FIG. 7 is a schematic drawing in a step subsequent to FIG. 6, and FIG. 2 and/or FIG. 3 may be regarded as a schematic drawing in a step subsequent to FIG. 7, but not limited thereto. As shown in FIGS. 1-3, the manufacturing method of the resistive memory device 101 in this embodiment may include the following steps. The via connection structure 18 is formed in the dielectric layer 16. The stacked structure 40 is formed on the via connection structure 18 and the dielectric layer 16. The insulating structure 30S is formed. The insulating structure 30S penetrates through a portion of the stacked structure 40 in the direction D1 and divides the stacked structure 40 into two memory cell units. The two memory cell units include a shared bottom electrode 20S, and the insulating structure 30S is directly disposed on the shared bottom electrode 20S. The manufacturing method in this embodiment may be applied to the first stacked structure 40-1 illustrated in FIG. 2 and/or the second stacked structure 40-2 illustrated in FIG. 3. Therefore, the via connection structure 18 may be the first via connection structure 18-1 or the second via connection structure 18-2, the insulating structure 30S may be the first insulating structure 30S-1 or the second insulating structure 30S-2, the shared bottom electrode 20S may be the first shared bottom electrode 20S-1 or the second shared bottom electrode 20S-2, and the two memory cell units including the shared bottom electrode 20S may be the first memory cell unit 40A and the second memory cell unit 40B or the third memory cell unit 40C and the fourth memory cell unit 40D.

Specifically, the manufacturing method of the resistive memory device in this embodiment may include but is not limited to the following steps. As shown in FIG. 3, the dielectric layer 14 and the dielectric layer 16 may be formed on the dielectric layer 10 and the electrically conductive line 12 after the steps of forming the electrically conductive line 12 in the dielectric layer 10. Subsequently, the via connection structure 18 may be formed penetrating through the dielectric layer 16 and the dielectric layer 14 located above the electrically conductive line 12 in the direction D1 for contacting and being electrically connected with the electrically conductive line 12. In some embodiments, the via connection structure 18 may be formed by filling an opening penetrating through the dielectric layer 16 and the dielectric layer 14 with an electrically conductive material and performing a planarization process for removing the electrically conductive material located outside the opening, and the top surface 18TS of the via connection structure 18 and the top surface 16TS of the dielectric layer 16 may be substantially coplanar accordingly, but not limited thereto. As shown in FIG. 5, the electrically conductive layer 20 may then be formed on the via connection structure 18 and the dielectric layer 16, the variable resistance material 22 may be formed on the electrically conductive layer 20, and the electrically conductive layer 26 may be formed on the variable resistance material 22. In some embodiments, before the step of forming the electrically conductive layer 26, the barrier layer 24 may be formed on the variable resistance material 22, and the electrically conductive layer 26 may be formed on the barrier layer 24. In addition, the capping layer 28 may be formed on the electrically conductive layer 26, but not limited thereto. Subsequently, as shown in FIG. 6, a patterning process may be performed to the capping layer 28, the electrically conductive layer 26, the barrier layer 24, the variable resistance material 22, and the electrically conductive layer 20 for forming the stacked structure 40, and the spacer structure 42 may be formed on the sidewall of the stacked structure 40. Therefore, the stacked structure 40 may include the shared bottom electrode 20S, the variable resistance material 22, the barrier layer 24, the electrically conductive layer 26, and the capping layer 28, and the electrically conductive layer 20 may be patterned to be the shared bottom electrodes 20S by the patterning process.

As shown in FIG. 7, the dielectric layer 44 may be formed. After the step of forming the dielectric layer 44, a trench TR may be formed penetrating through the capping layer 28, the electrically conductive layer 26, the barrier layer 24, and the variable resistance material 22 of the stacked structure 40 in the direction D1 for forming the two memory cell units including the shared bottom electrode 20S. In some embodiments, a portion of the shared bottom electrode 20S may be removed by the step of forming the trench TR (such as an etching process, but not limited thereto), and a bottom surface BS of the trench TR may be lower than the top surface 20TS of the shared bottom electrode 20S in the direction D1, but not limited thereto. Subsequently, as shown in FIG. 2 and/or FIG. 3, the insulating structure 30S may be formed in the trench TR. In some embodiments, an insulating material may be formed, the trench TR may be filled with a portion of the insulating material, and another portion of the insulating material may be formed outside the trench TR. A planarization process may then be performed for removing the insulating material formed outside the trench TR, and the insulating material remaining in the trench TR after the planarization process may become the insulating structure 30S. Therefore, a top surface 30TS of the insulating structure 30S and a top surface 40TS of the stacked structure 40 may be substantially coplanar, but not limited thereto.

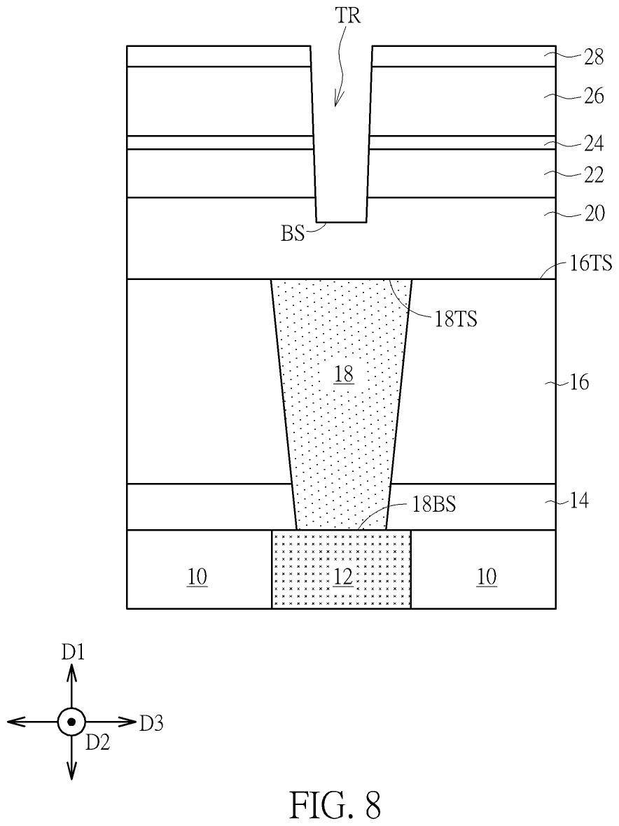

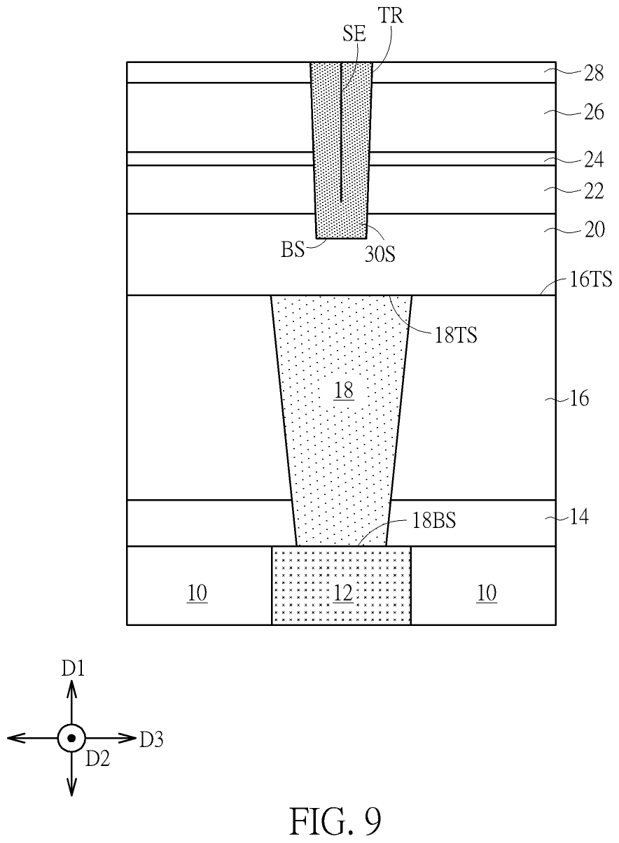

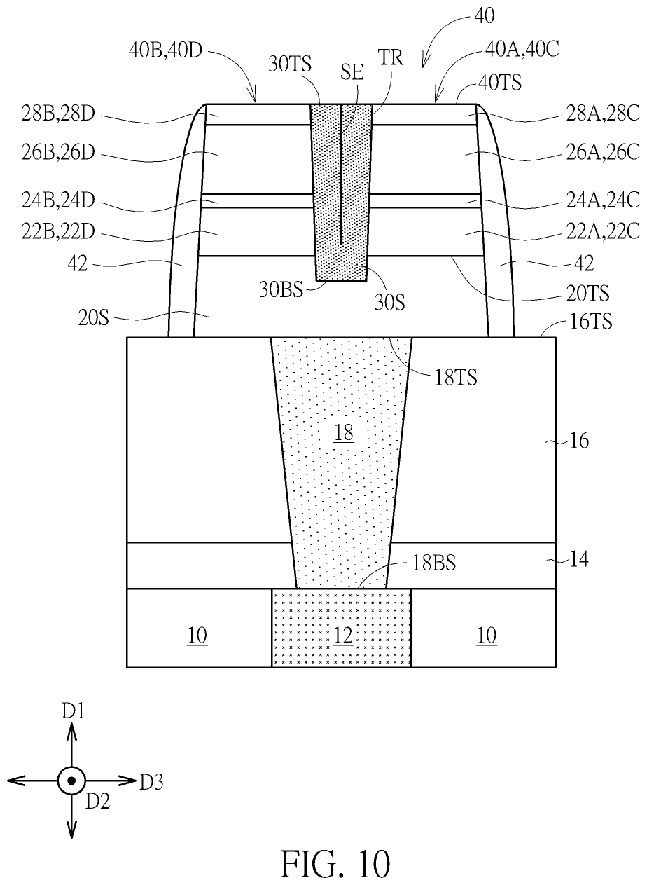

Please refer to FIGS. 1-3 and FIGS. 8-10. FIGS. 8-10 are schematic drawings illustrating a manufacturing method of the resistive memory device according to another embodiment of the present invention, wherein FIG. 9 is a schematic drawing in a step subsequent to FIG. 8, FIG. 10 is a schematic drawing in a step subsequent to FIG. 9, and FIG. 2 and/or FIG. 3 may be regarded as a schematic drawing in a step subsequent to FIG. 10, but not limited thereto. As shown in FIG. 8, the trench TR penetrating through the capping layer 28, the electrically conductive layer 26, the barrier layer 24, and the variable resistance material 22 in the direction D1 may be formed after the step of forming the capping layer 28. Subsequently, as shown in FIG. 9, the insulating structure 30S may be formed in the trench TR. As shown in FIG. 10, after the insulating structure 30S is formed, a patterning process may be performed to the capping layer 28, the electrically conductive layer 26, the barrier layer 24, the variable resistance material 22, and the electrically conductive layer 20 for forming the stacked structure 40, and the spacer structure 42 may be formed on the sidewall of the stacked structure 40. In some embodiments, the insulating structure 30S may be formed before the step of forming the stacked structure 40, and a portion of the insulating structure 30S may be removed by the step of forming the stacked structure 40, but not limited thereto. Subsequently, as shown in FIG. 2 and/or FIG. 3, the dielectric layer 44 may be formed after the insulating structure 30S, the stacked structure 40, and the spacer structure 42 are formed.

It is worth noting that, the manufacturing method of the resistive memory device in the present invention is not limited to the steps illustrated in FIGS. 4-7 and/or the steps illustrated in FIGS. 8-10, and the resistive memory device illustrated in FIGS. 1-3 may also be formed by other approaches according to some design considerations.

The following description will detail the different embodiments of the present invention. To simplify the description, identical components in each of the following embodiments are marked with identical symbols. For making it easier to understand the differences between the embodiments, the following description will detail the dissimilarities among different embodiments and the identical features will not be redundantly described.

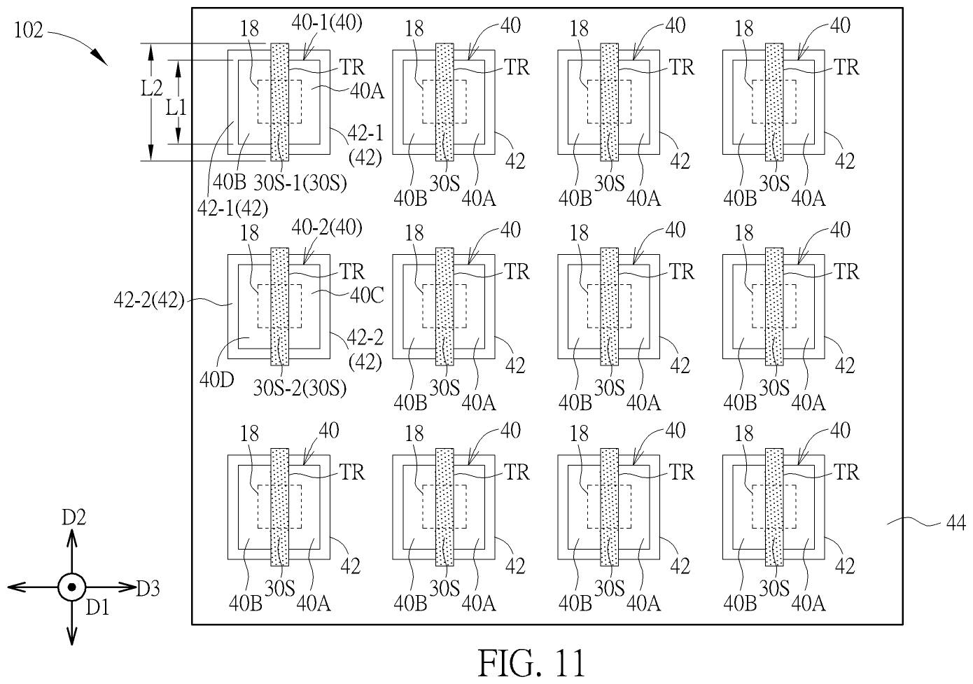

Please refer to FIG. 11. FIG. 11 is a top view schematic drawing illustrating a resistive memory device 102 according to a second embodiment of the present invention. As shown in FIG. 11, in the resistive memory device 102, each of the insulating structures 30S may extend in the direction D2, a length of each of the insulating structures 30S in the direction D2 may be greater than a length of the stacked structure 40 corresponding to this insulating structure 30S in the direction D2, and the spacer structure 42 may be divided into two portions separated from each other by the corresponding insulating structure 30S. For example, the first insulating structure 30S-1 and the second insulating structure 30S-2 may be disposed adjacent to each other in the direction D2 and separated from each other. A length L2 of the first insulating structure 30S-1 in the direction D2 may be greater than a length L1 of the first stacked structure 40-1 in the direction D2, and a length of the second insulating structure 30S-2 in the direction D2 may be greater than a length of the second stacked structure 40-2 in the direction D2. The first spacer structure 42-1 may include two portions separated from each other by the first insulating structure 30S-1, and the second spacer structure 42-2 may include two portions separated from each other by the second insulating structure 30S-2. The chance that each layer in the stacked structure 40 except the shared bottom electrode is not completely divided into two portions separated from each other by the insulating structure 30S when the formation position of the insulating structure 30S is shifted may be reduced by increasing the length of the insulating structure 30S in the direction D2 relatively. The manufacturing yield may be enhanced accordingly.

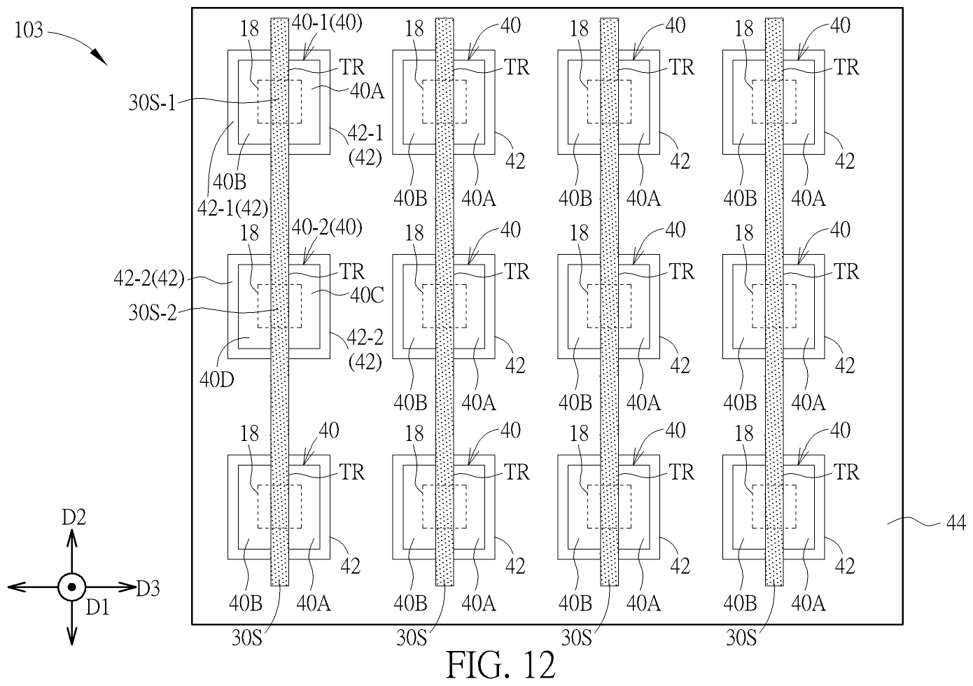

Please refer to FIG. 12. FIG. 12 is a top view schematic drawing illustrating a resistive memory device 103 according to a third embodiment of the present invention. As shown in FIG. 12, in the resistive memory device 103, one of the insulating structures 30S may be shared by the stacked structures 40 adjacent to one another in the direction D2, and the spacer structure 42 may be divided into two portions separated from each other by the corresponding insulating structure 30S. Therefore, the first insulating structure 30S-1 located corresponding to the first stacked structure 40-1 and the second insulating structure 30S-2 located corresponding to the second stacked structure 40-2 may be different portions of the insulating structure 30S extending in the direction D2 and directly connected with each other. In addition, a length of each of the insulating structures 30S in the direction D2 may be greater than the total length of the stacked structures 40 located corresponding to this insulating structure 30S in the direction D2.

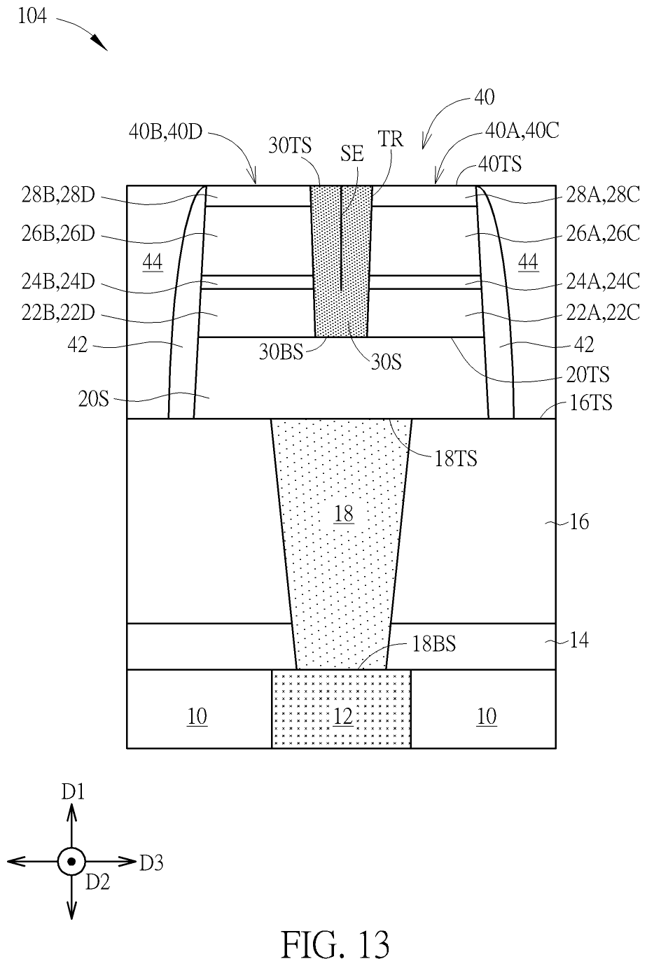

Please refer to FIG. 13. FIG. 13 is a schematic drawing illustrating a resistive memory device 104 according to a fourth embodiment of the present invention. As shown in FIG. 13, in the resistive memory device 104, the bottom surface 30BS of the insulating structure 30S (such as the bottom surface of the first insulating structure and/or the bottom surface of the second insulating structure described above) and the top surface 20TS of the shared bottom electrode 20S (such as the top surface of the first shared bottom electrode and/or the top surface of the second bottom shared electrode described above) may be substantially coplanar for avoiding removing a portion of the shared bottom electrode in the process of forming the trench TR (such as an etching process), the thickness of the shared bottom electrode 20S does not have to be increased for the process of forming the trench TR accordingly, and that is beneficial for the process of forming the stacked structure. In some embodiments, the etching selectivity between the variable resistance material and the shared bottom electrode 20S in the process of forming the trench TR may be improved by the material selection and matching of the variable resistance material and the shared bottom electrode 20S and/or modifying the process condition of the process of forming the trench TR for realizing the design where the bottom surface 30BS of the insulating structure 30S and the top surface 20TS of the shared bottom electrode 20S are substantially coplanar, but not limited thereto.

To summarize the above descriptions, in the resistive memory device and the manufacturing method thereof according to the present invention, the insulating structure penetrating through a portion of the stacked structure is used to divide the stacked structure into two memory cell units, and the two memory cell units include the shared bottom electrode. The purposes of improving the manufacturing yield, shrinking the dimension of a single memory cell unit, increasing the distribution density of the memory cell units, and/or improving the operation efficiency of the resistive memory device may be achieved accordingly.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A resistive memory device, comprising:
a dielectric layer;
a first via connection structure disposed in the dielectric layer;
a first stacked structure disposed on the first via connection structure and the dielectric layer; and
a first insulating structure penetrating through a portion of the first stacked structure in a vertical direction and dividing the first stacked structure into a first memory cell unit and a second memory cell unit, wherein the first memory cell unit and the second memory cell unit comprise a first shared bottom electrode, and the first insulating structure is disposed directly on the first shared bottom electrode.

2. The resistive memory device according to claim 1, wherein a portion of the first shared bottom electrode is disposed between the first insulating structure and the first via connection structure in the vertical direction.

3. The resistive memory device according to claim 1, wherein a bottom surface of the first insulating structure is lower than a top surface of the first shared bottom electrode in the vertical direction and higher than a top surface of the first via connection structure in the vertical direction.

4. The resistive memory device according to claim 1, wherein a bottom surface of the first insulating structure and a top surface of the first shared bottom electrode are coplanar.

5. The resistive memory device according to claim 1, wherein the first stacked structure comprises:
an electrically conductive layer disposed above the first shared bottom electrode in the vertical direction; and
a variable resistance material disposed between the first shared bottom electrode and the electrically conductive layer in the vertical direction, wherein the first insulating structure penetrates through the electrically conductive layer and the variable resistance material in the vertical direction.

6. The resistive memory device according to claim 5, wherein the first memory cell unit further comprises a first top electrode and a first variable resistance layer disposed between the first shared bottom electrode and the first top electrode in the vertical direction, and the second memory cell unit further comprises a second top electrode and a second variable resistance layer disposed between the first shared bottom electrode and the second top electrode in the vertical direction.

7. The resistive memory device according to claim 6, wherein the first variable resistance layer is a first portion of the variable resistance material, and the second variable resistance layer is a second portion of the variable resistance material separated from the first portion of the variable resistance material by the first insulating structure.

8. The resistive memory device according to claim 6, wherein the first top electrode is a first portion of the electrically conductive layer, and the second top electrode is a second portion of the electrically conductive layer separated from the first portion of the electrically conductive layer by the first insulating structure.

9. The resistive memory device according to claim 6, wherein the first insulating structure is directly connected with the first variable resistance layer, the second variable resistance layer, the first top electrode, and the second top electrode.

10. The resistive memory device according to claim 1, further comprising:
a spacer structure disposed on a sidewall of the first stacked structure.

11. The resistive memory device according to claim 10, wherein the spacer structure surrounds the first stacked structure in a direction perpendicular to the vertical direction, and the first insulating structure is directly connected with the spacer structure.

12. The resistive memory device according to claim 10, wherein the spacer structure comprises two portions separated from each other by the first insulating structure.

13. The resistive memory device according to claim 1, wherein a length of the first insulating structure in a horizontal direction is greater than a length of the first stacked structure in the horizontal direction.

14. The resistive memory device according to claim 1, further comprising:
a second via connection structure disposed in the dielectric layer;
a second stacked structure disposed on the second via connection structure and the dielectric layer; and
a second insulating structure penetrating through a portion of the second stacked structure in the vertical direction and dividing the second stacked structure into a third memory cell unit and a fourth memory cell unit, wherein the third memory cell unit and the fourth memory cell unit comprise a second shared bottom electrode, and the second insulating structure is disposed directly on the second shared bottom electrode.

15. The resistive memory device according to claim 14, wherein the first insulating structure and the second insulating structure extend in a horizontal direction respectively, and the first insulating structure and the second insulating structure are disposed adjacent to each other in the horizontal direction.

16. The resistive memory device according to claim 15, wherein the first insulating structure and the second insulating structure are separated from each other.

17. The resistive memory device according to claim 15, wherein the first insulating structure and the second insulating structure are different portions of an insulating structure extending in the horizontal direction and directly connected with each other.

18. The resistive memory device according to claim 14, wherein the first stacked structure and the second stacked structure are separated from each other, and the first shared bottom electrode and the second shared bottom electrode are separated from each other.

19. The resistive memory device according to claim 14, wherein the third memory cell unit further comprises a third top electrode and a third variable resistance layer disposed between the second shared bottom electrode and the third top electrode in the vertical direction, and the fourth memory cell unit further comprises a fourth top electrode and a fourth variable resistance layer disposed between the second shared bottom electrode and the fourth top electrode in the vertical direction.

20. The resistive memory device according to claim 19, wherein the third top electrode and the fourth top electrode are separated from each other by the second insulating structure, the third variable resistance layer and the fourth variable resistance layer are separated from each other by the second insulating structure, and the second insulating structure directly connected with the third variable resistance layer, the fourth variable resistance layer, the third top electrode, and the fourth top electrode.
